(19) United States
(12) Patent Application Publication
(10) Pub. No.: US 2025/0321251 A1
(43) Pub. Date: Oct. 16, 2025

(54) WIDE RANGE CURRENT SENSOR CHIPS

(71) Applicant: Dana Heavy Vehicle Systems Group, LLC, Maumee, OH (US)

(72) Inventors: Guillaume DESOURDY, Terrebonne (CA); Alexandre MAILLOUX, Prevost (CA)

(21) Appl. No.: 18/633,274

(22) Filed: Apr. 11, 2024

(51) Int. Cl. G01R 15/20; G01R 19/00

(52) U.S. Cl. CPC G01R 15/207; G01R 19/0092

(57) ABSTRACT

Systems are disclosed herein for a wide range current sensor chip, comprising: a single busbar including one or more constrictions; a first sensor with a first threshold range adapted to measure a first current range, positioned adjacent to one of the one or more constrictions spaced away therefrom by a first distance; and a second sensor with a second threshold range adapted to measure a second current range, positioned adjacent to one of the one or more constrictions and spaced away therefrom by a second distance, wherein a third current range of the wide range current sensor chip depends on the first threshold range, the second threshold range, the first distance, and the second distance.

### TECHNICAL FIELD

The present description relates generally to current sensor chips adapted to widen current amplitude ranges.

### BACKGROUND AND SUMMARY

Current sensors may be used for a wide variety of applications to determine a current through an electrical component. For example, current sensors may be incorporated into a circuit in an electric or hybrid vehicle to detect current to and from a traction battery. Current sensors may detect a magnetic field generated by the current flowing through the electrical component, and send a corresponding electrical signal which may be translated to a measured current value. Some current sensors may include field concentrators (e.g., current sensors with core), and other current sensors may not include field concentrators (e.g., current sensors without core).

Current sensors may have a current range, wherein the sensor may produce a resulting current measurement when measuring within the current range. The current range may depend on a magnetic field range bound by a lower threshold magnetic field strength and an upper threshold magnetic field strength. When exposed to magnetic fields outside of the range of a sensor (e.g., greater than the upper threshold magnetic field strength or less than the lower threshold magnetic field strength), the sensor may produce inaccurate current measurement results (e.g., outside an error tolerance) and/or become saturated. The current range may depend on a configuration of the sensor within a sensor chip. For example, if the current sensor is spaced further from the component through which the current to be measured flows, a lower magnetic field strength may be detected by the current sensor, thereby shifting the current range of the current sensor towards higher current amplitude values but not affecting the width (e.g., difference between the uppermost and lowermost current values) of the current range.

Some applications demand measurement of a high amplitude current and a low amplitude current, wherein a difference between the high amplitude current and the low amplitude current is greater than a width of the current range of a single current sensor. Thus, a single current sensor may not be able to measure a broad enough current amplitude range for some applications. For example, an electric vehicle that uses ultra-fast direct current (DC) charging may demand a current sensor chip that can accurately measure current for both a high amplitude current (e.g., 1000 A to 3000 A) during charging and a significantly lower amplitude current (e.g., 0 A to 1250 A) used during normal operation. Further, operational current may span a wide range due to the effect of fluctuating current demands of vehicle accessories (e.g., lights, infotainment systems, telematics systems, etc.) in addition varying current demands of a traction motor according to speed and torque ranges. Thus, measuring a wide range of current amplitudes may allow for detection of an undesired high spike in operational current. Field concentrators may adjust magnetic fields detected by a current sensor, and thus may be used to meet current range demands. However, field concentrators may increase complexity and resource demand of a current sensor system due to having additional components. Another attempt at measuring a wide current range may be to incorporate two or more sensor chips into two or more measurement circuits with two or more different sensors having two or more different threshold ranges in order to meet current range demand. However, such a multi circuit configuration may increase resource demand and complexity of the system.

Thus, example embodiments are disclosed herein that address at least some of the issues described above with a wide range current sensor chip, comprising: a single busbar including one or more constrictions; a first sensor with a first threshold range adapted to measure a first current range, positioned adjacent to one of the one or more constrictions and spaced away therefrom by a first distance; and a second sensor with a second threshold range adapted to measure a second current range, positioned adjacent to one of the one or more constrictions and spaced away therefrom by a second distance, wherein a third current range of the wide range current sensor chip depends on the first threshold range, the second threshold range, the first distance, and the second distance. Integrating two measurement circuits into a single wide range current sensor chip allows for a wide range of currents therethrough to be measured with decreased complexity and resource demand. The first sensor and the second sensor may be arranged in parallel or in series such that the first sensor may measure a first part of a desired current range of the wide range current sensor chip and the second sensor may measure a second part of the desired current range, wherein current values in the desired current range are included within the first part and/or the second part. There may be multiple exemplary configurations with current sensor placements, and busbar geometry wherein the desired current range may be achieved. In some examples, the first sensor and the second sensor have approximately the same threshold range, while the first current range and the second current range may not be the same. In this way, if the first sensor becomes saturated, the second sensor may still produce an accurate reading. Further, the wide range current sensor chip may provide short-circuit detection when both the first sensor and the second sensor become saturated.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

FIG. 1 shows a schematic diagram of a charging configuration for an electric vehicle, including a wide range current sensor chip according to the present disclosure.

FIG. 2 shows a top view of a dual constriction Y-shaped busbar.

FIG. 3 shows a top view of a dual constriction straight busbar.

FIG. 4 shows a top view of a single constriction straight busbar.

FIGS. 5A and 5B show a top view and a side view, respectively, of a first example of a wide range current sensor chip.

FIGS. 6A and 6B show a top view and a side view, respectively, of a second example of a wide range current sensor chip.

FIGS. 7A and 7B show a top view and a side view, respectively, of a third example of a wide range current sensor chip.

FIGS. 8A and 8B show a top view and a side view, respectively, of a fourth example of a wide range current sensor chip.

FIGS. 9A and 9B show a top view and a side view, respectively, of a fifth example of a wide range current sensor chip.

FIGS. 10A and 10B show a top view and a side view, respectively, of a sixth example of a wide range current sensor chip.

FIGS. 11A and 11B show a top view and a side view, respectively, of a seventh example of a wide range current sensor chip.

FIGS. 12A and 12B show a top view and a side view, respectively, of an eighth example of a wide range current sensor chip.

FIG. 13 shows an exemplary electrical system including a wide range current sensor chip.

FIG. 14 shows a table of configurations of the examples of FIGS. 5A-12B.

### DETAILED DESCRIPTION

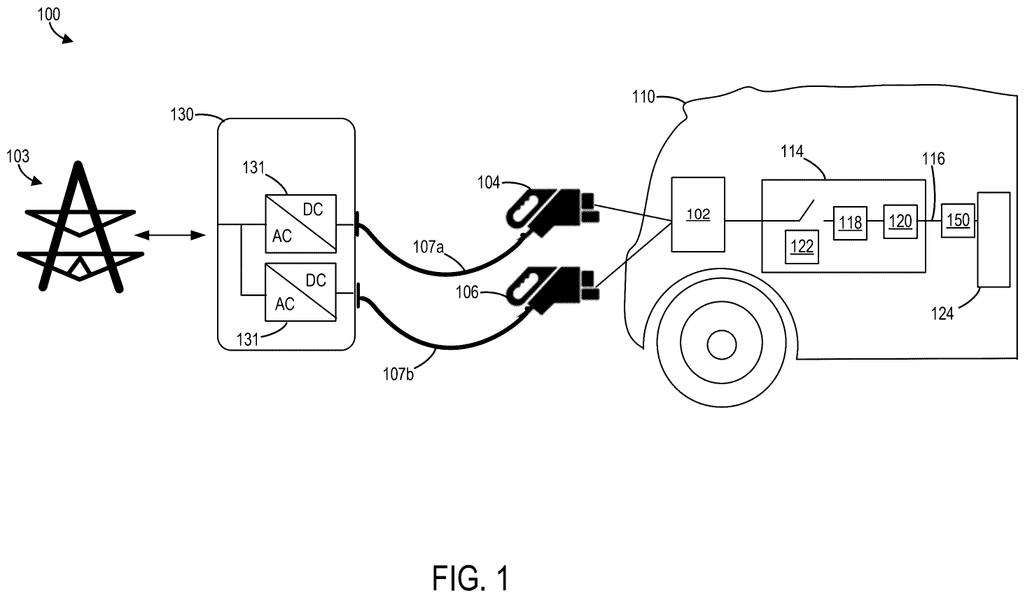

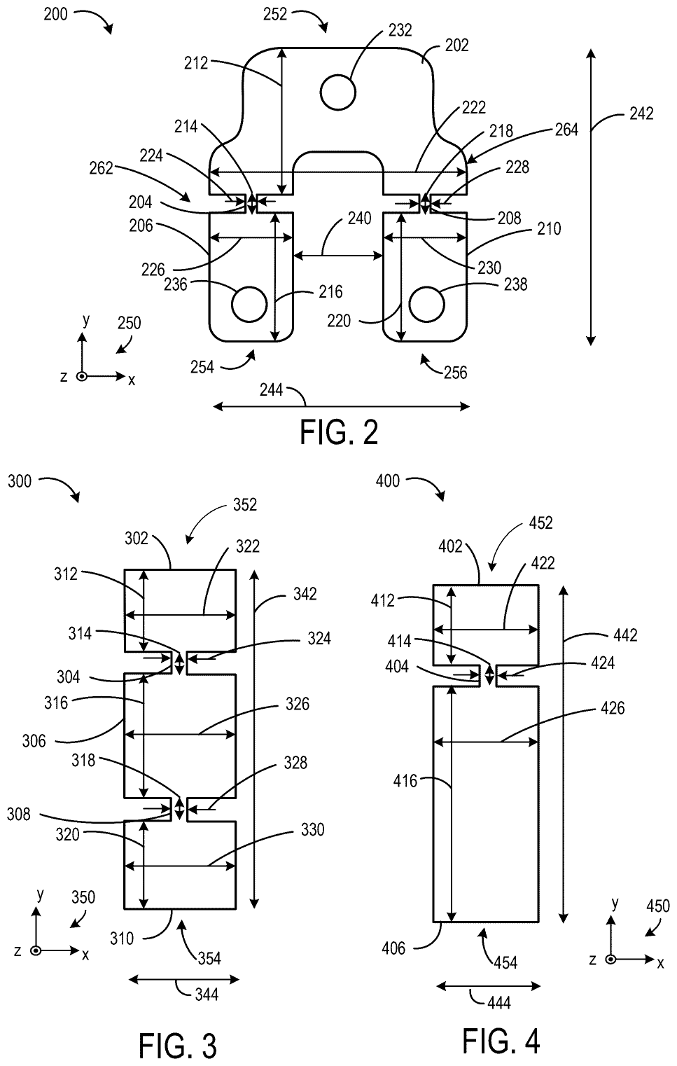

The following description relates to systems for wide range current sensor chips. For example, current may be measured in a charging system of a vehicle (e.g., an electric or hybrid vehicle) shown schematically in FIG. 1 by using one or more wide range current sensor chips according to the present disclosure. A wide range current sensor chip may comprise a busbar, such as a dual constriction Y-shaped busbar shown in FIG. 2, a dual constriction straight busbar shown in FIG. 3, or a single constriction straight busbar shown in FIG. 4. The wide range current sensor chip may further comprise two current sensors, each with a threshold range. The threshold range of a current sensor may be the range wherein the current sensor measures current accurately (e.g., within a threshold error of the actual current). The threshold range may be bound by a lower magnetic field strength and an upper magnetic field strength. Outside of the threshold range of a given sensor, the sensor may be saturated and/or the measurement results may not be accurate. For example, when a current sensor detects a magnetic field weaker than the lower magnetic field strength, the resulting current measurement may not be adequately accurate. When the current sensor detects a magnetic field greater than the upper magnetic field strength, the current sensor may become saturated. The two current sensors may have approximately the same threshold range in some examples. In other examples, the two current sensors may have different threshold ranges. The two current sensors may be arranged adjacent to and spaced away from the busbar. Specifically, the two current sensors may be positioned near one or more constrictions of the busbar. A current range measurable by a given current sensor may depend on the threshold range thereof and the configuration of the sensor and the component through which the current to be measured flows. Adjusting a configuration of a wide range current sensor chip may shift the current ranges of the sensors, thus enabling adjustment and widening of the current range of the wide range current sensor chip.

It will be understood that the threshold range of a current sensor is inherent to the sensor, and the current range of the sensor depends on both the threshold range and the configuration of the system including the current sensor. Further, the threshold range may not depend on the configuration of the system. As such, a type of sensor may be determined by the threshold range, rather than the current range. The current range of the current sensor may contribute to an overall current range of a wide range current sensor chip.

Variations may be made in current sensor types (e.g., high threshold range, or low threshold range) to achieve a desired current range of a wide range current sensor chip. As used herein, a “high threshold range” may indicate relatively high values are included within the threshold range and may not limit a size of the range. Similarly, a “low threshold range” may indicate low values are included within the threshold range and may not limit a size of the range. Positioning of current sensors may also be adjusted to achieve a desired current range of a wide range current sensor chip, regardless of whether the current sensors are the same type (e.g., have approximately the same threshold range). For example, distances between the constrictions and the sensors may be adjusted. Further, adjustments may be made to the busbar dimensions to achieve a desired current range of the wide range current sensor chip. For example, the widths of one or more of the constrictions of the busbar may be increased or decreased. Such adjustments may increase or decrease a magnetic field strength detected by a current sensor for a given current producing the magnetic field. In this way, the current range measurable by the current sensor may be shifted to include higher or lower current values. However, a size of the current range for the current sensor may not be increased or decreased, wherein the size of a range (e.g., threshold range, current range) may be the difference between the uppermost value and the lowermost value. Examples of wide range current sensor chips with a relatively small overlap in current ranges of the current sensors may have a wider sensor chip current range than examples of wide range current sensor chips with a relatively larger overlap between the current ranges of the current sensors.

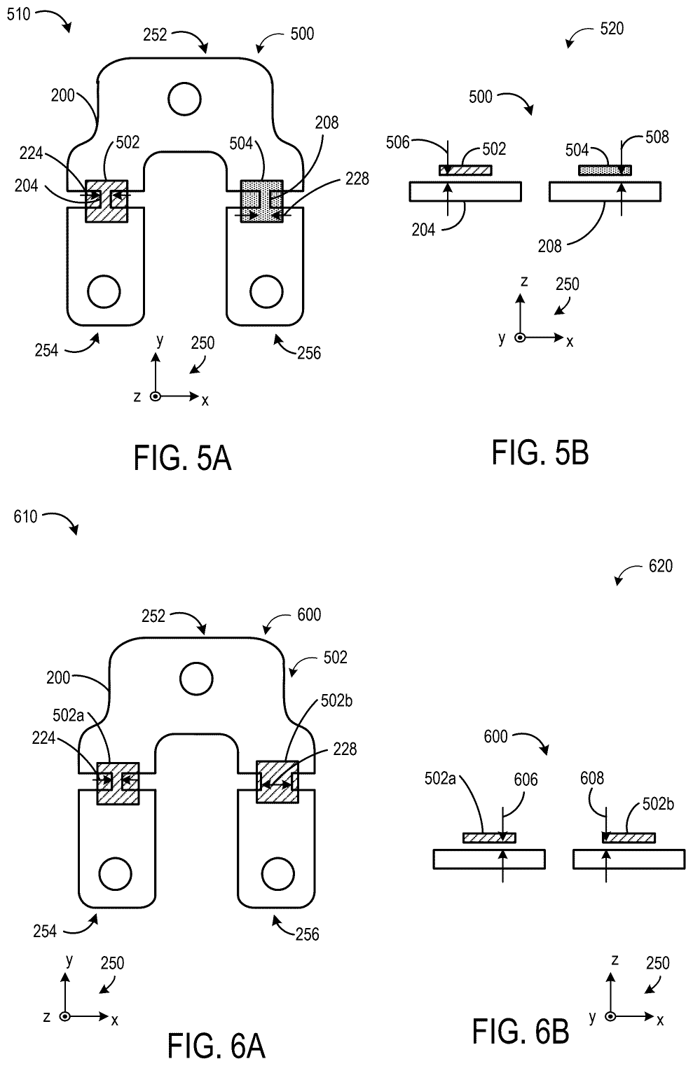

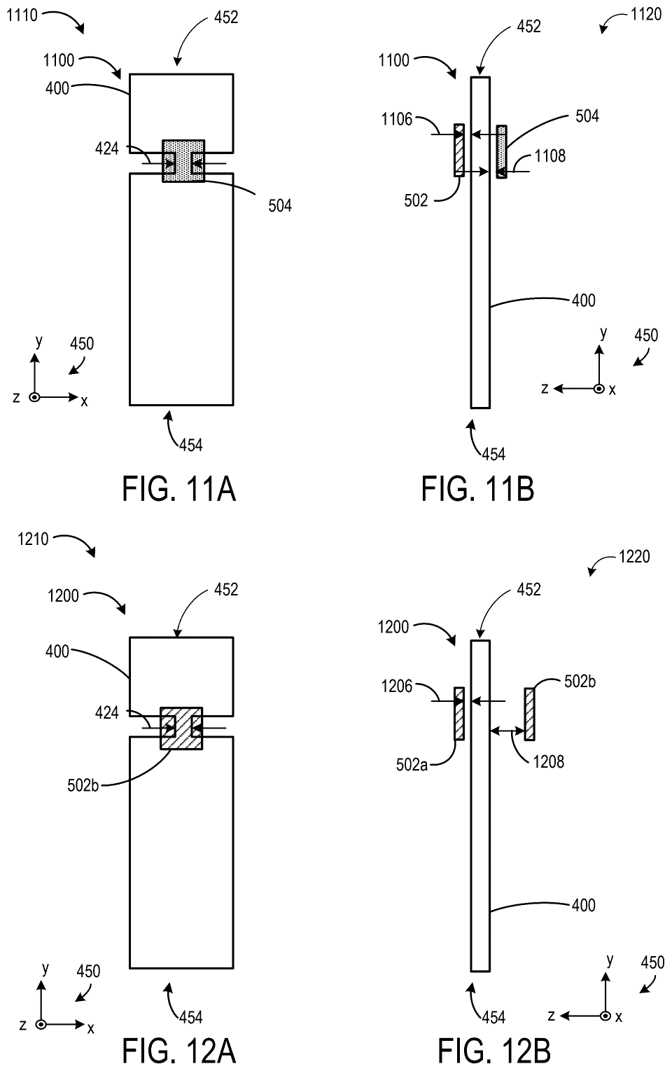

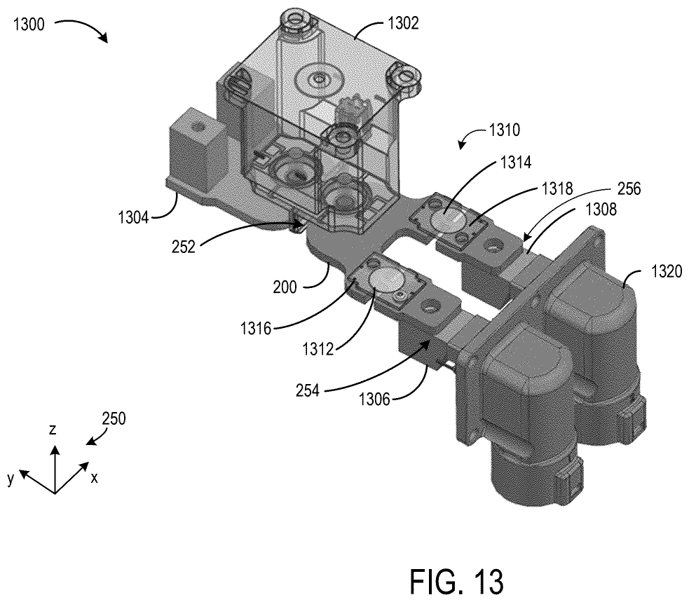

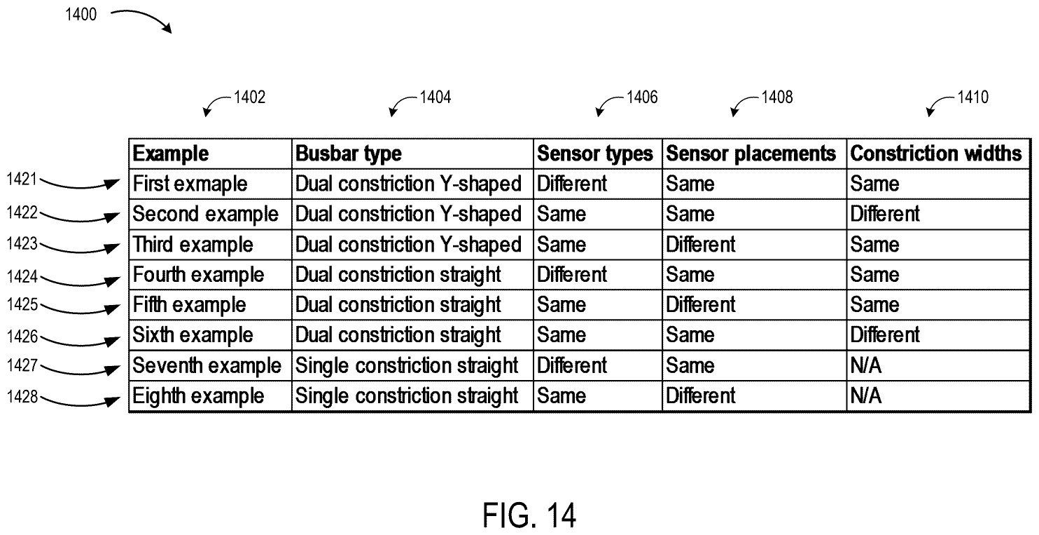

FIG. 14 shows a table of example combinations of busbar types (e.g., dual constriction Y-shaped busbar, dual constriction straight busbar, single constriction straight busbar), sensor types (e.g., sensors with approximately the same current range, sensors with different current ranges), and sensor placement (e.g., sensors spaced away from busbar by an approximately same distance, sensors spaced away from busbar by different distances). Wide range current sensor chips with the example combinations of FIG. 14 are shown in FIGS. 5A-12B. Specifically, examples of wide range current sensor chips including the dual constriction Y-shaped busbar are shown in FIGS. 5A-7B, examples of wide range current sensor chips including the dual constriction straight busbar are shown in FIGS. 8A-10B, and examples of wide range current sensor chips including the single constriction busbar are shown in FIGS. 11A-12B. One of the examples shown in FIGS. 5A-12B may be chosen according to spacial configurations of an application. For example, due to different dimensions and volumes of the wide range current sensor chip examples disclosed herein, one or more of the wide range current sensor chip examples may fit within a given electrical system configuration. Further, the wide range current sensor chip examples allow for integration into an electrical system with the two sensors in parallel or in series. For example, a wide rage current sensor chip may include a dual constriction Y-shaped busbar in an application wherein a parallel configuration is demanded (e.g., a dual battery system), and a straight busbar (e.g., dual constriction straight busbar or single constriction straight busbar) in an application wherein a series configuration is demanded (e.g., a single battery system). An exemplary electrical system including a wide range current sensor chip according to the present disclosure is shown in FIG. 13. The wide range current sensor chip examples disclosed herein may integrate two current measurement circuits to increase a range of measurable current amplitudes. Thus, a wide range current sensor chip may be positioned within the charging system of FIG. 1 to measure current of both a relatively higher amplitude current, such as during charging of a battery of the vehicle, and a relatively lower amplitude current, such as during operation of the vehicle. In this way, a wide range of current amplitudes (e.g., a large size current range) may be measured by using a single wide range current sensor chip rather than multiple conventional current sensor chips, thereby reducing resource demand. Further, the range of measurable current amplitudes may be widened without including field concentrators. Thus, resource demand may be further reduced.

It is also to be understood that the specific assemblies and systems illustrated in the attached drawings, and described in the following specification are exemplary embodiments of the inventive concepts defined herein. For purposes of discussion, the drawings are described collectively. Thus, like elements may be commonly referred to herein with like reference numerals and may not be re-introduced.

Turning now to FIG. 1, a schematic diagram is shown of a charging configuration 100 for charging a DC output 116 to a high voltage battery 124, including a wide range current sensor chip 150 according to the present disclosure. In some examples, the charging configuration 100 may include two or more batteries such as the battery 124. In an exemplary embodiment, DC output 116 may be an electric vehicle 110. However, other DC outputs such as battery powered generators have been considered within a scope of the disclosure. Charging configuration 100 may include an energy grid 103. In some examples, energy delivered by energy grid 103 may be at least partially derived from renewable energy sources such as wind or solar. Energy grid 103 may be electrically coupled to a vehicle charging station 130. Internally, the vehicle charging station 130 includes AC to DC converters 131 to convert energy from electric vehicle 110 to energy grid 103 or from energy grid 103 to electric vehicle 110 to charge electric vehicle 110.

Vehicle charging station 130 electrically couples energy from energy grid 103 to electric vehicle 110 through a first wire 107a and high voltage charge coupler (HV CCS) 104 and/or through a second wire 107b and a high voltage megawatt charge coupler (HV MCS) 106. In one example, HV CCS 104 may be selected when electric vehicle 110 is a personal electric vehicle while HV MCS 106 may be selected when electric vehicle 110 is a commercial sized electric vehicle, such as a large truck or bus. HV CCS 104 and/or HV MCS 106 may be electrically coupled to the DC output 116 via a charge coupler 102. Charge coupler 102 may connect to an IPCB 114.

IPCB 114 may be configured to prevent short circuit current spikes from reaching DC output 116. IPCB 114 may include a fuse device 118, a cooling system 120 and a charging interface connector 122. Short circuit current spikes may be caused by degradation of AC to DC converters 131 internal to the vehicle charging station 130 or may be caused by a break in first wire 107a or second wire 107b. Further, IPCB 114 may be configured to allow current to flow from energy grid 103 to DC output 116 or from DC output 116 back to energy grid 103.

A high speed fuse may act as a current limiting device and may be used as a fuse device for an IPCB, such as IPCB 114 of FIG. 1. When a current flowing through the high speed fuse is above a threshold current, the high speed fuse may be current limiting and reduce a peak let-through short-circuit current of the high speed fuse, thereby reducing thermal and mechanical forces imposed on equipment upon exposure to a short-circuit if the short-circuit occurs. For example, the short-circuit current may be reduced to a level within a rated tolerance of the charging equipment. The charging equipment may refer to any of the components electrically coupled to the DC output 116 including: charge coupler 102, first wire 107a, second wire 107b, HV CCS 104, HV MCS 106, and AC to DC converter 131.

The wide range current sensor chip 150 may be positioned in the charging configuration 100 depending on where a measurement of current is desired. For example, the wide range current sensor chip 150 may be electrically coupled to the battery 124 and the DC output 116. In this way, the wide range current sensor chip 150 may measure current during charging of the battery 124 as described above, and during discharge of the battery 124 (e.g., during operation of the vehicle 110). The wide range current sensor chip 150 may detect magnetic field strength wherein current is to be measured and send a corresponding electrical signal, for example to a controller of the vehicle 110. Because a high current may be used during charging to reduce a time to charge the battery 124 and a relatively lower current may be used during discharge of the battery 124, the wide range current sensor chip 150 may be more suitable to retrieve current measurement over a range including both the high current and the lower current, than a conventional sensor chip which may have a current range that includes only one of the high current or the lower current. Further, the wide range current sensor chip 150 may be desired over two or more sensor chips with different ranges to cover the high current and the lower current due to a reduced complexity, resource demand, and volume.

The position of the wide range current sensor chip 150 is exemplary and non-limiting. A wide range current sensor chip such as the wide range current sensor chip 150 may be placed in additional or alternative locations within an electrical system (e.g., the charging configuration 100) according to where current monitoring is demanded. For example, a wide range current sensor chip may be placed between charge coupler 102 and IPCB 114 and/or between AC to DC converter 131 and first wire 107a. For another example, the wide range current sensor chip 150 may be included in a power distribution box that manages DC power in an electric vehicle. Additionally or alternatively, the wider range current sensor chip may be positioned at a battery inlet, such as an inlet of the battery 124. One or more wide range current sensor chips according to one or more embodiments of the present disclosure may be included in an electrical system, such as in a vehicle, according to desired current measurements.

The wide range current sensor chip 150 may include a busbar with one or more constrictions, a first current sensor spaced away from the busbar by a first distance, and a second current sensor spaced away from the busbar by a second distance. The first sensor may have a first threshold range and a first current range, and the second sensor may have a second threshold range and a second current range. The wide range current sensor chip 150 may have a third current range, wherein the third current range is broader than the first current range and the second current range. The broader width of third current range may be achieved by different configurations of wide range current sensor chips, including different combinations of busbar type, sensor types, sensor placements, and constriction widths, as described further below.

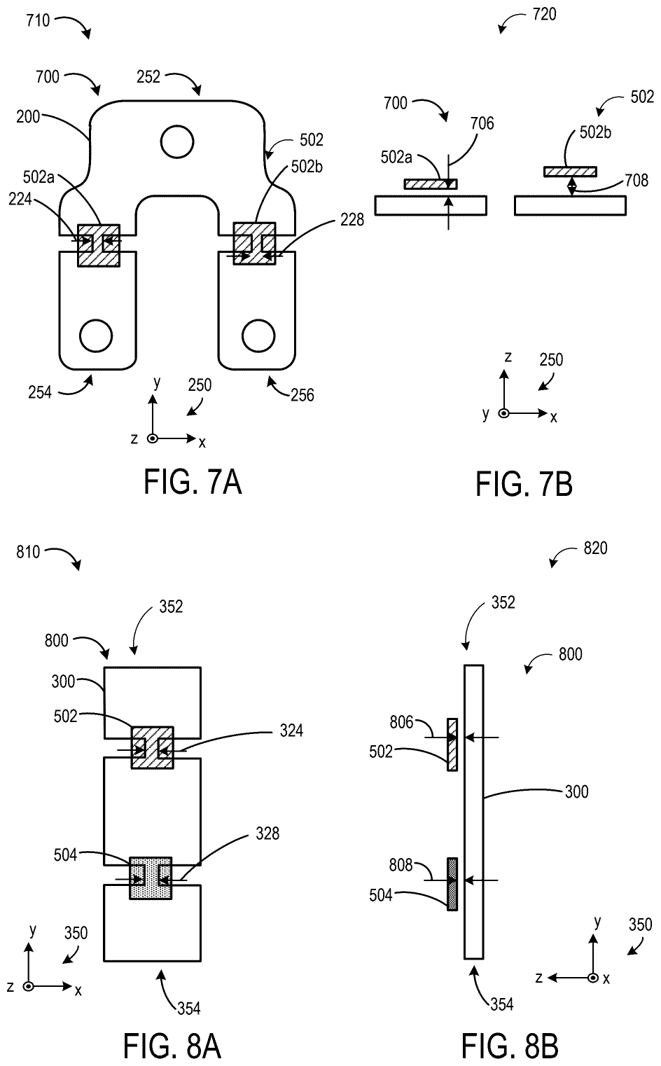

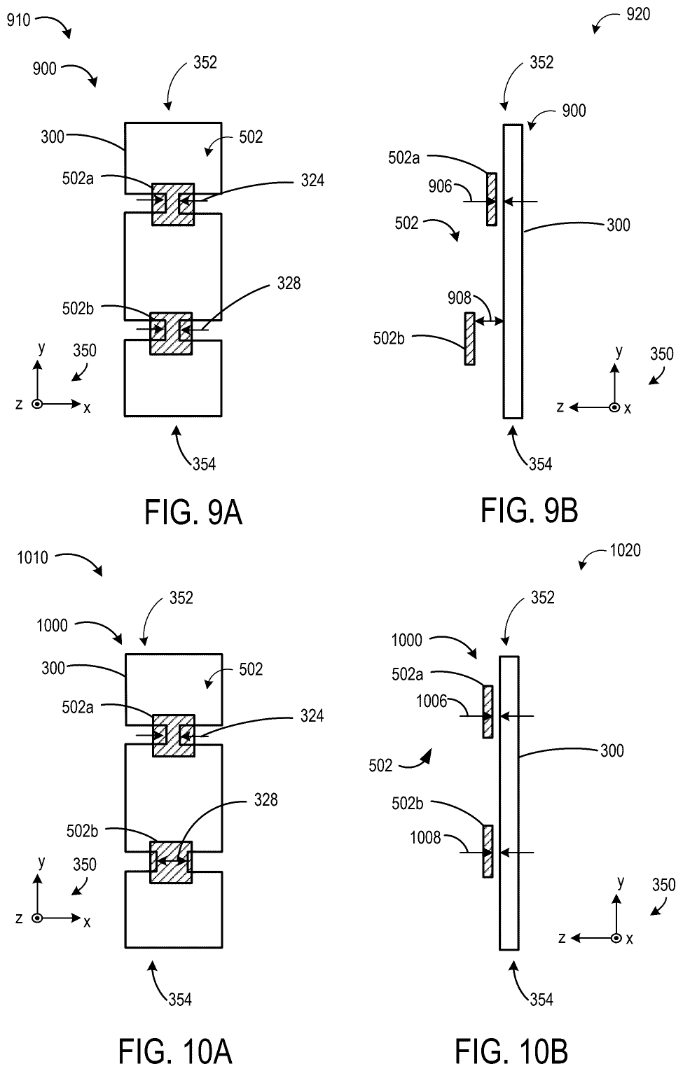

FIG. 14 shows a table 1400 summarizing wide range current sensor chip examples described herein according to such combinations. The table 1400 includes a first column 1402 identifying the examples, a second column 1404 of busbar type, a third column 1406 of sensor types, a fourth column 1408 of sensor placements, and a fifth column 1410 of constriction widths. There may be further examples of wide range current sensor chips not shown in the table 1400 with different combinations of the features of columns 1404, 1406, 1408, and 1410. The examples provided in the table 1400 are introduced in reference to FIG. 14 and described further below in reference to FIGS. 5A-12B. For example, first example of row 1421 may be a first example 500 shown in FIGS. 5A-5B, second example of row 1422 may be a second example 600 of FIGS. 6A-6B, third example of row 1423 may be a third example 700 of FIGS. 7A-7B, fourth example of row 1424 may be a fourth example shown in FIGS. 8A-8B, fifth example of row 1425 may be a fifth example shown in FIGS. 9A-9B, sixth example of row 1426 may be a sixth example 1000 shown in FIGS. 10A-10B, seventh example of row 1427 may be a seventh example 1100 of FIGS. 11A-11B, and eighth example of row 1428 may be an eighth example 1200 shown in FIGS. 12A-12B.

The busbar type shown in column 1404 may be a dual constriction Y-shaped busbar (e.g., dual constriction Y-shaped busbar 200 shown in FIGS. 2 and 5A-7B), a dual constriction straight busbar (e.g., dual constriction straight busbar 300 shown in FIGS. 3 and 8A-10B), or a single constriction straight busbar (single constriction straight busbar 400 shown in FIGS. 4 and 11A-12B). A dual constriction Y-shaped busbar and a dual constriction straight busbar may have a first constriction and a second constriction. The first current sensor may be positioned adjacent to the first constriction and the second current sensor may be positioned adjacent to the second constriction. In contrast, a single constriction straight busbar may have only one constriction. The first current sensor and the second current sensor may be positioned adjacent to the single constriction, and on opposite sides of the constriction from one another. The busbar type may depend on circuit and/or spacial configurations of an application. For example, a wide range current sensor chip including a dual constriction Y-shaped busbar may be used for applications wherein three electrical couplings may be desired, and/or a parallel configuration of the current sensors. As another example, a wide range current sensor chip may include a dual constriction straight busbar in systems wherein a smaller width of sensor chip is demanded and/or a series configuration of current sensors is demanded.

The sensor types shown in column 1406 may indicate whether the first threshold range and the second threshold range are approximately the same. For example, if the first threshold range and the second threshold range are approximately the same, the first current sensor and the second current sensor may be referred to herein as the same type (e.g., a complementary cell of column 1406 is labeled “same”). If the first threshold range and the second threshold range are not approximately the same (e.g., greater than 5% difference in upper thresholds and/or lower thresholds defining the threshold ranges), the first current sensor and the second sensor may be referred to herein as different types (e.g., a complementary cell of column 1406 is labeled “different”). A wide range current sensor chip including two or more different sensor types may broaden the current range, regardless of sensor placements and constriction widths. For example, incorporating a sensor with a low threshold range (corresponding to a low current range) and a sensor with a high threshold range (corresponding to a high current range) may result in a wide range current sensor chip with a combined current range wider than the sizes of the low current range and the high current range. Including current sensors of the same sensor type may reduce resource demand as a number of demanded sensor types may be reduced. A wide range current sensor chip including two (or more) of the same sensor type may include modifications to a busbar constriction or placement of the sensors in order to broaden the current range of the wide range current senor chip. Thus, a wide range current sensor chip may include two sensors of different types or two sensors of the same type according to resource demand, current range demand, and/or busbar geometry (e.g., number and widths of constrictions).

The sensor placements of column 1408 may indicate whether the first current sensor and the second current sensor are positioned approximately equidistantly from the busbar. For example, if the first distance by which the first current sensor is spaced away from the busbar and the second distance by which the second current senor is spaced away from the busbar are approximately equal, the first current sensor and the second current sensor may be referred to herein as having approximately the same placement away from the busbar (e.g., a complementary cell of column 1408 is labeled “same”). Conversely, if the first distance and the second distance are not approximately the same, the first current sensor and the second current sensor may be referred to herein as having different sensor placements (e.g., a complementary cell of column 1408 is labeled “different”). The first distance and the second distance may be the shortest measurable distances between the current sensors and a point on a surface of the busbar. For example, the first distance and the second distance may be perpendicular to the surface of the busbar.

A distance by which a current sensor is spaced from the busbar may relate to a magnetic field strength the current sensor detects. For example, a greater distance between the busbar and the current sensor may subject the current sensor to weaker magnetic field, compared to a relatively shorter distance. Because the current sensor may convert magnetic field strength to an electrical signal conveying the current, the current sensor may be spaced further from the busbar to increase values of the current range of the current sensor (e.g., increase low threshold and high threshold defining the current range). As described above, the current range may be a range of current amplitudes that a current sensor may measure when accounting for a configuration (e.g., sensor placement and constriction width) of the wide range current sensor chip wherein the current sensor is incorporated in addition to the threshold range. Thus, two of the same type of sensor (e.g., two sensors with approximately the same threshold range) may be placed differently (e.g., different distances from the busbar) to achieve different current ranges, thus broadening a current range of a wide range current sensor chip. Similarly, two different sensor types may be placed differently to further adjust the combined current range of the wide range current sensor chip. In this way, the combined current range of a wide range current sensor chip may depend on relative positioning of the current sensors. A desired distance by which the current sensor is spaced from the busbar may be maintained by installing the current sensor on top of fiberglass laminate of a printed circuit board (PCB), therefore allowing the PCB to act as a spacer. In another example, the current sensor may be installed on stand-offs in the form of press-in inserts, wherein a shoulder of the stand-off holds the current sensor at a desired distance from the busbar. In yet another example, the current sensor may be installed on a non-conductive shim interposed between the current sensor and the busbar. In yet another example, the current sensor may be overmolded with plastic such that the current sensor is embedded in the plastic to maintain the desired distance.

The constriction widths in column 1410 may indicate whether constrictions widths of the busbar (if the busbar has more than one constriction) are approximately equal. A constriction may be a local narrowing of width in the busbar. A dual constriction busbar may comprise two constricitons. A single constriction busbar may comprise one busbar. In other examples, a busbar may comprise two or more constrictions. For example, a dual constriction Y-shaped busbar or a dual constriction straight busbar may comprise a first constriction with a first width and a second constriction with a second width. If the first width and the second width are approximately the same, the constriction widths of the busbar may be referred to herein as having the same constriction width (e.g., a complementary cell in column 1410 is labeled “same”). Alternatively, if the first width and the second width are not approximately the same, the constriction widths of the busbar may be referred to herein as having different constriction widths (e.g., a complementary cell in column 1410 is labeled “different”). The constriction widths may affect the magnetic field perceived by the sensors. For example, a larger constriction width may shift the current range of a current sensor to lower values compared to a current sensor of the same type arranged near a constriction with a smaller constriction width. Thus, the constriction widths may be different in order to increase a combined range of a wide range current sensor chip comprising two of the same sensor type. Constriction widths may also be adjusted for a wide range current sensor chip comprising different sensor types to adjust the combined current range thereof. The constriction width of a current sensor chip comprising a single constriction may also be adjusted to shift the current range of the wide range current sensor chip to include higher or lower currents.

A wide range current sensor chip according to the present disclosure may include a busbar comprising one or more constrictions, a first current sensor with a first threshold range and a first current range spaced away from the busbar by a first distance, and a second current sensor with a second threshold range and a second current range spaced away from the busbar by a second distance. A type of busbar, a relative difference of the first distance and the second distance, a relative difference between the first threshold range and the second threshold range may be adjusted to achieve a desired current range of the wide range current sensor chip. Further, for wide range current sensor chips including two or more constrictions, widths of the constrictions and a difference therebetween may also be adjusted in order to achieve a desired combined current range. Further, a span of the combined current range may be greater than both the first current range and the second current range due to the configurations described herein. In this way, the wide range current sensor chip may be used in applications demanding measurement of high amplitude current and low amplitude current, wherein the high amplitude current and the low amplitude current are too different for a single current sensor to measure adequately (e.g., accurately, without saturation, etc.). Each of the exemplary combinations of the table 1400 are described further below.

Turning to FIG. 2, a dual constriction Y-shaped busbar 200 is shown. Reference axes 250, including an x-axis, a y-axis, and a z-axis, are shown in FIGS. 2, 5A-7B, and 13 for comparison of exemplary wide range current sensor chips including the dual constriction Y-shaped busbar 200. For example, the dual constriction Y-shaped busbar 200 may be flat and parallel with an x-y plane with an even thickness in the z-direction. Additionally or alternatively, current sensors may be positioned relative to the dual constriction Y-shaped busbar 200 along the z-axis, as described further in regards to FIGS. 5A-7B. When referencing direction, positive may refer to in the direction of the arrow of the y-axis, x-axis, and z-axis and negative may refer to in the opposite direction of the arrow of the y-axis, x-axis, and z-axis. A filled circle may represent an arrow and axis facing toward, or positive to, a view. An unfilled circle may represent an arrow and an axis facing away, or negative to, a view.

The dual constriction Y-shaped busbar 200 may include a first portion 202 and two arms (a first arm 262 and a second arm 264) extending therefrom (e.g., in a negative y-direction). The first portion 202, the first arm 262, and the second arm 264 may be integrally formed to construct the dual constriction Y-shaped busbar 200. Further, the dual constriction Y-shaped busbar 200 may be constructed from a conductive material, such as metal. The first arm 262 and the second arm 264 may extend along the y-axis and be parallel to one another. The first arm 262 and the second arm 264 may be spaced away from each other and may electrically couple via the first portion 202. In this way, the dual constriction Y-shaped busbar 200 may allow for a parallel configuration within an electrical system. The dual constriction Y-shaped busbar 200 may be adapted to configure two or more current sensors in parallel. For example, when dual constriction the Y-shaped busbar 200 is incorporated into an electrical circuit, electrical current may flow from a first end 252 of the first portion 202 and be split such that current flows towards a second end 254 of the first arm 262 and a third end 256 of the second arm 264. In another example, current may be directed oppositely, from the second end 254 and the third end 256 towards the first end 252.

The first arm 262 may include a first constriction 204 and a second portion 206, and the second arm 264 may include a second constriction 208 and a third portion 210. The first constriction 204 and the second constriction 208 may be rectangular in shape. In other examples, the first constriction 204 and the second constriction 208 may have different shapes. For example, the first constriction 204 and the second constriction 208 may be formed as one or more through holes in the first arm 262 and the second arm 264, respectively, resulting in a locally narrower width of the first arm 262 and the second arm 264. Additionally or alternatively, the first constriction 204 and the second constriction 208 may have rounded corners. The first constriction 204 and the second constriction 208 may be local narrowings in the dual constriction Y-shaped busbar 200. In other examples, the constrictions may be local widenings rather than narrowings. As used herein, a “constriction” may be a local narrowing or widening or other local modification of a busbar wherein dimensions and geometry thereof may be adjusted to widen a current sensor chip current range, and “constriction” may not indicate a shape thereof (e.g., rectangular, rounded, through hole, indent, symmetrical, asymmetrical, etc.). Further, as used herein, a “busbar” may be any conductor of any shape that carries current which generates a magnetic field, and the busbars described herein are provided for examples. The second portion 206 and the third portion 210 may be rectangular with rounded corners at the second end 254 and the third end 256, respectively. Further, the dual constriction Y-shaped busbar 200 may include a first hole 232, a second hole 236, and a third hole 238. For example, the first hole may be formed into the first portion 202 near the first end 252. The second hole 236 may be formed into the second portion 206 near the second end 254. The third hole 238 may be formed into the third portion 210 near the third end 256. The first hole 232, the second hole 236, and the third hole 238 may provide points of electrical coupling with other components of an electrical circuit (e.g., the assembly 1300 of FIG. 13) wherein the dual constriction Y-shaped busbar 200 is integrated. Further, the first hole 232, the second hole 236, and the third hole 238 may be used to secure the dual constriction Y-shaped busbar 200 to the other components. For example, the second hole 236 and the third hole 238 may be connection points to a two pole connector (e.g., a battery) wherein both are at the same electrical potential. In this way, multiple poles may allow for flow of more current and/or reduce packing volume of the system. In the same or other examples, the first hole 232 may be a connection point to a contactor.

The first constriction 204 and the second hole 236 may be aligned centrally with a lateral center of the second portion 206. For example, a vertical axis may intersect lateral centers of all three of the first constriction 204, the second portion 206, and the second hole 236. Likewise, the second constriction 208 and the third hole 238 may be aligned centrally with a lateral center of the third portion 210. For example, a vertical axis may intersect lateral centers of all three of the second constriction 208, the third portion 210, and the third hole 238. Similarly, the first hole 232 may be laterally centered in the first portion 202.

The first constriction 204 may extend between the first portion 202 and the second portion 206. In this way, the second portion 206 may be coupled (e.g., electrically and physically) to the first portion 202 via the first constriction 204. Likewise, the second constriction 208 may extend between the first portion 202 and the third portion 210 such that the third portion 210 is coupled (e.g., electrically and physically) to the first portion 202. The second portion 206 and the third portion 210 may be spaced apart by a distance 240. Further, the first constriction 204 and the second constriction 208 may be spaced apart by a distance greater than the distance 240. In this way, the dual constriction Y-shaped busbar 200 may allow for an electrical circuit configuration wherein two current sensors are positioned in parallel, as further described below in regards to FIGS. 5A-7B.

The first portion 202, the first constriction 204, the second portion 206, the second constriction 208, and the third portion 210 may have a first portion height 212, a first constriction height 214, a second portion height 216, a second constriction height 218, and a third portion height 220, respectively. The first constriction height 214 may be approximately the same as the second constriction height 218. Additionally or alternatively, the second portion height 216 may be approximately the same as the third portion height 220. Additionally or alternatively, the first constriction height 214 and the second constriction height 218 may both be less than the second portion height 216, the third portion height 220, and the first portion height 212. A dual constriction Y-shaped busbar height 242 may be the largest dimension parallel with the y-axis. For example, the dual constriction Y-shaped busbar height 242 may be a sum of the first portion height 212, the first constriction height 214, and the second portion height 216. Additionally or alternatively, the dual constriction Y-shaped busbar height 242 may be a sum of the first portion height 212, the second constriction height 218, and the third portion height 220. As used herein, “height” may indicate that the referenced dimension is parallel with a y-axis. Further, the heights may be aligned approximately parallel with a direction of current flow through the referenced components.

The first portion 202, the first constriction 204, the second portion 206, the second constriction 208, and the third portion 210 may also have a first portion width 222, first constriction width 224, second portion width 226, second constriction width 228, and a third portion width 230, respectively. The second portion width 226 may be approximately the same as the third portion width 230. A dual constriction Y-shaped busbar width 244 may be the largest dimension parallel with the x-axis. For example, the dual constriction Y-shaped busbar width 244 may be approximately the same as the first portion width 222. Additionally or alternatively, the dual constriction Y-shaped busbar width 244 may be a sum of the second portion width 226, the distance 240, and the third portion width 230. The first constriction width 224 may be approximately the same as the second constriction width 228, in some examples. In other examples, the first constriction width 224 may be greater or less than the second constriction width 228. As used herein, “width” may indicate that the referenced dimension is parallel with an x-axis. Further, widths may be perpendicular to heights and approximately perpendicular to the direction of current flow through the referenced components. Alternatively, “width” may refer to a size of a range of values.

The dual constriction Y-shaped busbar may support two connections, one at the second end 254 and one at the third end 256. For example, in electrical systems wherein two batteries may be included, each battery may be electrically coupled to one of the second portion 206 or the third portion 210. In this way, current through only one of the arms (e.g., the first arm 262 or the second arm 264) may be measured and the other arm not measured may be calculated using the measured current.

In some examples, the dual constriction Y-shaped busbar 200 may be symmetrical across a vertical axis (e.g., parallel with the y-axis). In other examples, the dual constriction Y-shaped busbar 200 may not be symmetrical, for example due to a difference between the first constriction width 224 and the second constriction width 228. As described above, the relative widths of the first constriction 204 and the second constriction 208 may be adjusted to reach a desired current range of a wide range current sensor chip comprising the dual constriction Y-shaped busbar 200, such as the examples shown in FIGS. 5A-7B. Additionally or alternatively, a distance (e.g., along the z-axis) between sensors and the dual constriction Y-shaped busbar 200 may be adjusted to reach a desired current range of a wide range current sensor chip, such as the examples shown in FIGS. 5A-7B. Additionally or alternatively, the current sensor types (e.g., high threshold range or low threshold range) included in a wide range current sensor chip may be adjusted to reach a desired current range of a wide range current sensor chip comprising the dual constriction Y-shaped busbar 200, such as the examples shown in FIGS. 5A-7B. Three examples of wide range current sensor chips comprising the dual constriction Y-shaped busbar 200 are shown in FIGS. 5A-7B with different combinations of constriction widths, sensor placements, and sensor types.

Turning to FIGS. 5A and 5B, a first example 500 of a wide range current sensor chip is shown in a top view 510 and a side view 520, respectively. The first example 500 may include the dual constriction Y-shaped busbar 200, a first sensor 502 positioned adjacent to the first constriction 204, and a second sensor 504 positioned adjacent to the second constriction 208. The first constriction width 224 and the second constriction width 228 may be approximately equal in the first example 500. Further, the sensor placements of the first sensor 502 and the second sensor 504 may be approximately the same. For example, a first distance 506 between the first sensor 502 and the dual constriction Y-shaped busbar 200 and a second distance 508 between the second sensor 504 and the dual constriction Y-shaped busbar 200 may be approximately the same. The first sensor 502 and the second sensor 504 may not be the same current sensor type. For example, the first sensor 502 and the second sensor 504 may be current sensors (e.g., transducers) with different threshold ranges, as indicated by different shading in FIGS. 5A and 5B. In this way, the first example 500 may have a broader current range than a sensor chip with only one of the first sensor 502 or the second sensor 504. Further, an electrical circuit comprising the first example 500 may be more compact and less complex than an electrical circuit comprising a combination of a first sensor chip with the first sensor 502 and a second sensor chip with the second sensor 504.

Turning to FIGS. 6A and 6B, a second example 600 of a wide range current sensor chip is shown in a top view 610 and a side view 620, respectively. The second example 600 may comprise a dual constriction Y-shaped busbar 200, and two first sensors 502. For example, the second example 600 may comprise a first first sensor 502a positioned adjacent to the first constriction 204 and a second first sensor 502b positioned adjacent to the second constriction 208. The first first sensor 502a and the second first sensor 502b may have approximately the same threshold range. A third distance 606 between the first first sensor 502a and the dual constriction Y-shaped busbar 200 may be approximately the same as a fourth distance 608 between the second first sensor 502b and the dual constriction Y-shaped busbar 200. The first constriction width 224 may be smaller than the second constriction width 228 in the second example 600. Thus, the first constriction width 224 and the second constriction width 228 may be different. In this way, a first current range of the second first sensor 502b may be different from a second current range of the first first sensor 502a. Therefore, a size of a third current range of the second example 600 may be wider than the current ranges of the first sensors 502a, 502b. In this way, the second example 600 may have a wider current range than a sensor chip with a single sensor, such as the first sensor 502. In this way, a wide range of current amplitudes may be measured by the second example 600.

Turning to FIGS. 7A and 7B, a third example 700 of a wide range current sensor chip is shown in a top view 710 and a side view 720, respectively. The third example may comprise the dual constriction Y-shaped busbar 200, the first first sensor 502a positioned adjacent to the first constriction 204, and the second first sensor 502b positioned adjacent to the second constriction 208. As described above, the first first sensor 502a and the second first sensor 502b may have approximately the same threshold ranges. The first constriction 204 and the second constriction 208 may have approximately the same widths. In other words, the first constriction width 224 may be approximately equal to the second constriction width 228. A fifth distance 706 between the first first sensor 502a and the dual constriction Y-shaped busbar 200 may be less than a sixth distance 708 between the second first sensor 502b and the dual constriction Y-shaped busbar 200. Thus, the second first sensor 502b may experience a weaker magnetic field strength than the first first sensor 502a, allowing for the second first sensor 502b to measure greater current without saturating than the first first sensor, despite them having approximately the same threshold range. In this way, the third example 700 may have a wider current range than a sensor chip with a single first sensor 502. Further, resource demand may be reduced by reducing a number of current sensor types to a single current sensor type.

Turning to FIG. 3, a dual constriction straight busbar 300 is shown. Reference axes 350, including an x-axis, a y-axis, and a z-axis, are shown in FIGS. 3 and 8A-10B for comparison of exemplary wide range current sensor chips including the dual constriction straight busbar 300. For example, the dual constriction straight busbar 300 may be flat in an x-y plane. Additionally or alternatively, current sensors may be positioned relative to the dual constriction straight busbar 300 along the z-axis.

The dual constriction straight busbar 300 may comprise a first portion 302, a second portion 306, a third portion 310, a first constriction 304 and a second constriction 308. The first portion 302, second portion 306, third portion 310, first constriction 304 and second constriction 308 may be integrally formed to construct the dual constriction straight busbar 300. Further, the dual constriction straight busbar 300 may be constructed from a conductive material, such as metal. Electrical components may be electrically coupled to the first portion 302 and the third portion 310. For example, when the dual constriction straight busbar 300 is incorporated into an electrical circuit, electrical current may flow from a first end 352 at the first portion 302 towards a second end 354 at the third portion 310. In another example, current may be directed oppositely, from the second end 354 towards the first end 352.

The first constriction 304 may be between the first portion 302 and the second portion 306. The second portion 306 may be between the first constriction 304 and the second constriction 308. The second constriction 308 may be between the second constriction 208 and the third portion 310. Thus, current may flow from the first end 352 to the second end 354 or vice versa via the first portion 302, the first constriction 304, the second portion 306, the second constriction 308, and the third portion 310. In this way, the dual constriction straight busbar 300 may be configured for current sensors positioned adjacent to the first constriction 304 and the second constriction 308 to be in series. Thus, a same amount of current may be measured by each sensor of a wide range current sensor chip comprising the dual constriction straight busbar 300.

The first portion 302, second portion 306, third portion 310, first constriction 304 and second constriction 308 may be rectangular in shape. The first portion 302, second portion 306, third portion 310, first constriction 304 and second constriction 308 may have a first portion height 312, second portion height 316, third portion height 320, first constriction height 314 and second constriction height 318. The first constriction height 314 may be approximately the same as the second constriction height 318, in at least some examples. In other examples, the first constriction height 214 may be greater than or less than the second constriction height 218. For example, the first portion height 312 and the third portion height 320 may be approximately the same. Additionally or alternatively, the first portion height 312 and the second portion height 316 may be approximately the same. In other examples, the second portion height 316 may be greater than the first portion height 312. In still further examples, the second portion height 316 may be less than the first portion height 312. Relative dimensions of the first portion height 312, the second portion height 316, and the third portion height 320 may vary. A dual constriction straight busbar height 342 may be a sum of the first portion height 312, the first constriction height 314, the second portion height 316, the second constriction height 318, and the third portion height 320.

The first portion 302, second portion 306, third portion 310, first constriction 304 and second constriction 308 may also have a first portion width 322, second portion width 326, third portion width 330, first constriction width 324 and second constriction width 328. The first portion width 322, the second portion width 326, and the third portion width 330 may be approximately equal. In other examples, the first portion width 322, the second portion width 326, and the third portion width 330 may be different. A dual constriction straight busbar width 344 may be the greatest dimension parallel with the x-axis of the dual constriction straight busbar 300. For example, the dual constriction straight busbar width 344 may be approximately equal to the first portion width 322, the second portion width 326, and/or the third portion width 330. The first constriction width 324 and the second constriction width 328 may both be less than the first portion width 322, the second portion width 326, and the third portion width 330. In some examples, the first constriction width 324 and the second constriction width 328 may be approximately the same. In other examples, the first constriction width 324 may be greater than or less than the second constriction width 328. The dual constriction straight busbar width 344 may be significantly smaller than the dual constriction Y-shaped busbar width 244 of FIG. 2.

The dual constriction straight busbar 300 may be adapted to configure two or more sensors in series in an electrical circuit. The relative widths of the first constriction 304 and the second constriction 308 may be adjusted to reach a desired current range in a wide range current sensor chip comprising the dual constriction straight busbar 300, such as the examples shown in FIGS. 8A-10B. Additionally or alternatively, placement of sensors may be adjusted by changing distances (e.g., along the z-axis) between current sensors and the dual constriction straight busbar 300 to reach a desired current range of a wide range current sensor chip, such as the examples shown in FIGS. 8A-10B. Additionally or alternatively, the types of current sensors included in a wide range current sensor chip may be adjusted to reach a desired current range of a wide range current sensor chip comprising the dual constriction straight busbar 300, such as the examples shown in FIGS. 8A-10B. Three examples of wide range current sensor chips comprising the dual constriction straight busbar 300 are shown in FIGS. 8A-10B with different combinations of constriction widths, sensor placements, and sensor types.

Turning to FIGS. 8A and 8B, a fourth example 800 of a wide range current sensor chip is shown in a top view 810 and a side view 820, respectively. The fourth example 800 may comprise the dual constriction straight busbar 300, the first sensor 502, and the second sensor 504. The first constriction width 324 and the second constriction width 328 may be approximately the same in the fourth example 800. A seventh distance 806 between the first sensor 502 and the dual constriction straight busbar 300 may be approximately the same as an eighth distance 808 between the second sensor 504 and the dual constriction straight busbar 300. As described above, the first sensor 502 and the second sensor 504 may have different threshold ranges and be placed approximately the same distance from constrictions with approximately the same widths. Therefore, the first sensor 502 and the second sensor 504 may have different current ranges. Thus, the fourth example 800 may have a broader current range than a sensor chip including only one of the first sensor 502 or the second sensor 504.

Turning to FIGS. 9A and 9B, a fifth example 900 of a wide range current sensor chip is shown in a top view 910 and a side view 920, respectively. The fifth example 900 may comprise the dual constriction straight busbar 300, and two first sensors 502, wherein the first first sensor 502a may be adjacent to the first constriction 304 and the second first sensor 502b may be adjacent to the second constriction 308. As described above, the first first sensor 502a and the second first sensor 502b may have approximately the same threshold ranges. The first constriction width 324 may be approximately the same as the second constriction width 328. A ninth distance 906 between the first first sensor 502 and the dual constriction straight busbar 300 may be less than a tenth distance 908 between the second first sensor 502b and the dual constriction straight busbar 300. In this way, the first first sensor 502a and the second first sensor 502b may have different current ranges, despite having approximately the same threshold range. Thus, the fifth example 900 may have a wider current range than a sensor including a single current sensor, such as the first sensor 502.

Turning to FIGS. 10A and 10B, a sixth example 1000 of a wide range current sensor chip is shown in a top view 1010 and a side view 1020, respectively. The sixth example 1000 may comprise the dual constriction straight busbar 300, the first first sensor 502a, and the second first sensor 502b. As described above, the first first sensor 502a and the second first sensor 502b may have approximately the same threshold ranges. An eleventh distance 1006 between the first first sensor 502a and the dual constriction straight busbar 300 may be approximately the same as a twelfth distance 1008 between the second first sensor 502b and the dual constriction straight busbar 300. The first constriction width 324 may be less than the second constriction width 328. In this way, the first first sensor 502a and the second first sensor 502b may have different current ranges, despite having approximately the same threshold range. Thus, the sixth example 1000 may have a wider current range than a sensor including a single current sensor, such as the first sensor 502.

Turning to FIG. 4, a single constriction straight busbar 400 is shown. Reference axes 450, including an x-axis, a y-axis, and a z-axis, are shown in FIGS. 4 and 11A-12B for comparison of exemplary wide range current sensor chips including the single constriction straight busbar 400. For example, the single constriction straight busbar 400 may be flat in an x-y plane. Additionally or alternatively, current sensors may be positioned relative to the single constriction straight busbar 400 along the z-axis.

The single constriction straight busbar 400 may comprise a first portion 402, a second portion 406, and a first constriction 404. The first portion 402, second portion 406, and first constriction 404 may be integrally formed to construct the single constriction straight busbar 400. Further, the single constriction straight busbar 400 may be constructed from a conductive material, such as metal. A first electrical component may be electrically coupled to the first portion 402 and a second electrical component may be electrically coupled to the second portion 406. For example, when the single constriction straight busbar 400 is incorporated into an electrical circuit, electrical current may flow from a first end 452 at the first portion 402 towards a second end 454 at the second portion 406. In another example, current may be directed oppositely, from the second end 454 towards the first end 452.

The first portion 402, second portion 406, and first constriction 404 may be rectangular in shape. The first constriction 404 may be between the first portion 402 and the second portion 406. In this way, current may flow through the single constriction straight busbar 400 via the first portion 402, the first constriction 404, and the second portion 406. Two sensors may be arranged adjacent to the first constriction 404. For example, a first sensor may be positioned in a positive z-direction from the single constriction straight busbar 400 and a second sensor may be positioned in a negative z-direction from the single constriction straight busbar 400. In this way, the first sensor and the second sensor may both measure the current passing through the first constriction 404. Thus, the single constriction straight busbar 400 may allow for current sensors to be arranged in series in an electrical circuit.

The first portion 402, the second portion 406, and the first constriction 404 may have a first portion height 412, a second portion height 416, and a first constriction height 414, respectively. The first constriction height 414 may be less than the first portion height 412 and the second portion height 416. In some examples, the first portion height 412 may be approximately the same as the second portion height 416. In other examples, the first portion height 412 may be greater than or less than the second portion height 416. A single constriction straight busbar height 442 may be a sum of the first portion height 412, the second portion height 416, and the first constriction height 414.

The first portion 402, the second portion 406, and the first constriction 404 may have a first portion width 422, a second portion width 426, and a first constriction width 424. The first constriction width 424 may be smaller than the first portion width 422 and the second portion width 426. As such, the first constriction 404 may be a local narrowing of the single constriction straight busbar 400. A single constriction straight busbar width 444 may be the greatest of the first portion width 422, the second portion width 426, and the first constriction width 424. For example, the single constriction straight busbar width 444 may be approximately the same as the first portion width 422 and/or the second portion width 426.

The first constriction width 424 may be adjusted to reach a desired current range of a wide range current sensor chip comprising the single constriction straight busbar 400, such as the examples shown in FIGS. 11A-12B. Additionally or alternatively, distances (e.g., along the z-axis) between sensors and the single constriction straight busbar 400 may be adjusted to reach a desired current range of a wide range current sensor chip comprising the single constriction straight busbar 400, such as the examples shown in FIGS. 11A-12B. Additionally or alternatively, the types of sensors included in a wide range current sensor chip may be adjusted to reach a desired current range of a wide range current sensor chip comprising the single constriction straight busbar 400, such as the examples shown in FIGS. 11A-12B. Two examples of wide range current sensor chips incorporating the single constriction straight busbar 400 are shown in FIGS. 11A-12B with different combinations of sensor placements and sensor types.

Turning to FIGS. 11A and 11B, a seventh example 1100 of a wide range current sensor chip is shown in a top view 1110 and a side view 1120, respectively. The seventh example 1100 may comprise the single constriction straight busbar 400, the first sensor 502, and the second sensor 504. A thirteenth distance 1106 between the first sensor 502 and the single constriction straight busbar 400 may be approximately the same as a fourteenth distance 1108 between the second sensor 504 and the single constriction straight busbar 400. As described above, the first sensor 502 and the second sensor 504 may have different threshold ranges. In this way, the current range of the seventh example 1100 may be wider than the current ranges of the first sensor 502 and the second sensor 504.

Turning to FIGS. 12A and 12B, an eighth example 1200 of a wide range current sensor chip is shown in a top view 1210 and a side view 1220, respectively. The eighth example 1200 may comprise the single constriction straight busbar 400, the first first sensor 502a and the second first sensor 502b. As described above, the first first sensor 502a and the second first sensor 502b may have approximately the same current range. A fifteenth distance 1206 between the first first sensor 502a and the single constriction straight busbar 400 may be less than a sixteenth distance 1208 between the second first sensor 502b and the single constriction straight busbar 400. In this way, a current range of the eighth example 1200 may be wider than the current range of a current sensor chip comprising a single first current sensor 502, or multiple first current sensors 502 having a similar configuration (e.g., spaced approximately the same distance away from constrictions with approximately the same widths).

In either of the seventh example 1100 of FIGS. 11A-11B and the eighth example 1200 of FIGS. 12A-12B, the first constriction width 424 may be adjusted in order to adjust the current ranges of the seventh example 1100 and the eighth example 1200, respectively. For example, increasing the first constriction width 424 may shift the current range higher and decreasing the first constriction width 424 may shift the current range lower. Thus, the current range of a wide range current sensor chip comprising the single constriction straight busbar 400 may be tuned according to the first constriction width 424.

Further, the examples provided herein including the first example 500 of FIGS. 5A-5B, the second example 600 of FIGS. 6A-6B, the third example 700 of FIGS. 7A-7B, the fourth example of FIGS. 8A-8B, the fifth example 900 of FIGS. 9A-9B, the sixth example 1000 of FIGS. 10A-10B, the seventh example 1100 of FIGS. 11A-11B, and the eighth example 1200 of FIGS. 12A-12B, are exemplary and non-limiting. As such, other configurations of a wide range current sensor chip may not depart from the scope of this disclosure. For example, a wide range current sensor chip may include a dual constriction busbar (e.g., a dual constriction Y-shaped busbar or a dual constriction straight busbar) with different constriction widths, and two different sensor types that are arranged at different distances from the busbar. In this way, the sensor types, sensor placements, and constriction widths may all adjust the current range of the wide range current sensor chip. Different combinations of busbar geometry (e.g., shape, dimensions such as constriction width, etc.), sensor placements, and sensor types, as described above may be included in further examples of wide range current sensor chips.

Further still, a number of constrictions and/or a number current sensors included within a wide range current sensor chip may not be limited to the examples described herein. A wide range current sensor chip may comprise a busbar with one or more constrictions and one or more current sensors. For example, a busbar may have three constrictions and three current sensors may be arranged adjacent to the three constrictions. In this way, an even broader range of current amplitudes may be measured by a single wide range current sensor chip.

Turning to FIG. 13, an assembly 1300 is shown, including a wide range current sensor chip 1310 according to one or more embodiments of the present disclosure. For example, the assembly 1300 may be included in a power distribution box of an electric or hybrid vehicle (e.g., an electric truck) that uses high charging current during charging of one or more traction batteries and low operating current during driving of the vehicle. The high charging current and the low operating current may not be measured by a single sensor chip comprising a single current sensor due to a greater difference between the high charging current and low operating current being larger than a difference between an uppermost current and a lowermost current of the single sensor current range.

The wide range current sensor chip 1310 may be adapted to measure both the high charging current and the low operating current. The wide range current sensor chip 1310 comprises the dual constriction Y-shaped busbar 200, a first current sensor 1312, and a second current sensor 1314. The first current sensor 1312 and the second current sensor 1314 may be the same type in some examples, and different types in other examples, as described above. The first current sensor 1312 may be mounted to a first PCB 1316 adjacent to the second end 254 and the second current sensor 1314 may be mounted to a second PCB 1318 adjacent to the third end 256. In this way, each current sensor may have a corresponding PCB. In other examples, two or more current sensors may be mounted on a single PCB that extends across the dual constriction Y-shaped busbar 200 (or a different busbar). Further, the first PCB 1316 and the second PCB 1318 (or a single PCB) may be positioned such that the first current sensor 1312 and the second current sensor 1314 are positioned adjacent to the first constriction 204 and the second constriction 208.

The first end 252 may be electrically coupled to a contactor 1302, the second end 254 may be electrically coupled to a first pole 1306 of a high-voltage (HV) DC connector 1320, and the third end 256 may be electrically coupled to a second pole 1308 of the HV DC connector 1320. In this way, the first current sensor 1312 and the second current sensor 1314 may be configured in parallel (due to the geometry of the dual constriction Y-shaped busbar 200) and current may flow from the contactor 1302 to the HV DC connector 1320, or vice versa. For example, the HV DC connector 1320 may be coupled to one or more batteries (e.g., a traction battery in a vehicle, such as the charging configuration 100 of FIG. 1).

The first current sensor 1312 and the second current sensor 1314 may detect a magnetic field produced by the current and send a corresponding electrical signal via the first PCB 1316 and the second PCB 1318. The current may be measured by the wide range current sensor chip 1310, including a high amplitude current and a low amplitude current, wherein the high amplitude current and the low amplitude current are too different to be measured by a single current sensor. The wide current range of the wide range current sensor chip 1310 may be achieved by adjusting the sensor types, sensor placements, and constriction geometry and size, as described above.

The assembly 1300 may further include additional components, in some examples. For example, a second busbar 1304 may electrically and physically connect the contactor 1302 to other components, for example components of a power distribution unit. For another example, additionally or alternatively, a busbar carrier may structurally support the contactor 1302 and the dual constriction Y-shaped busbar 200. For yet another example, additionally or alternatively, a thermal interface comprising a thermally insulating material may thermally insulate the dual constriction Y-shaped busbar 200 from other components in the assembly 1300. The assembly 1300 may be included in a vehicle, such as an electric or hybrid vehicle, in order to measure a wide range of current amplitudes through components of interest in an electrical system thereof during charging and operation. In other examples, a different busbar type (e.g., dual constriction straight busbar or a single constriction straight busbar) may configure the first sensor and the second sensor in series, rather than in parallel as shown in FIG. 13. Further, the wide range current sensor chip 1310 and/or another embodiment of the present disclosure may be incorporated into any assembly wherein other components are electrically coupled thereto, additionally or alternatively, without departing from the scope of this disclosure. Such an assembly may be incorporated into a vehicle charging configuration (e.g., the charging configuration 100 of FIG. 1) or any suitable electrical circuit wherein measurement of current therethrough is desired.

The technical effect of the wide range current sensor chip disclosed herein is to measure a broader range of current amplitudes with a single wide range current sensor chip in order to decrease resource demand and complexity of an electrical system demanding measurement of both high current amplitude and low current amplitude, wherein a current range of a single current sensor may not be able to measure the high current amplitude and the low current amplitude. For example, the wide range current sensor chip may be included in a charging configuration of an electric or hybrid vehicle to measure high amplitude current (e.g., electrical power on the order of megawatts) during charging of a traction battery thereof, and relatively lower amplitude current during discharge of the battery to drive the vehicle. In this way, the wide range current sensor chip may measure a wider range of currents.

The disclosure also provides support for a wide range current sensor chip, comprising: a single busbar including one or more constrictions, a first sensor with a first threshold range adapted to measure a first current range, positioned adjacent to one of the one or more constrictions and spaced away therefrom by a first distance, and a second sensor with a second threshold range adapted to measure a second current range, positioned adjacent to one of the one or more constrictions and spaced away therefrom by a second distance, wherein a third current range of the wide range current sensor chip depends on the first threshold range, the second threshold range, the first distance, and the second distance. In a first example of the system, the wide range current sensor chip is adapted to be incorporated into an electrical circuit with the first sensor and the second sensor in parallel. In a second example of the system, optionally including the first example, the wide range current sensor chip is adapted to be incorporated into an electrical circuit with the first sensor and the second sensor in series. In a third example of the system, optionally including one or both of the first and second examples, the busbar comprises only one constriction, and wherein the first sensor is positioned adjacent to and spaced away from a first side of a constriction, and the second sensor is positioned adjacent to and spaced away from a second side of the constriction, where the first side is opposite the second side. In a fourth example of the system, optionally including one or more or each of the first through third examples, the first threshold range and the second threshold range are approximately the same, and wherein the first distance and the second distance are different. In a fifth example of the system, optionally including one or more or each of the first through fourth examples, the first threshold range is not the same as the second threshold range, and wherein the first distance and the second distance are approximately the same. In a sixth example of the system, optionally including one or more or each of the first through fifth examples, the busbar comprises two constrictions, and wherein the first sensor is positioned adjacent to and spaced away from a first constriction having a first constriction width by the first distance, and wherein the second sensor is positioned adjacent to and spaced away from a second constriction having a second constriction width by the second distance. In a seventh example of the system, optionally including one or more or each of the first through sixth examples, the third current range further depends on the first constriction width, the second constriction width, and a difference therebetween.

The disclosure also provides support for a wide range current sensor chip, comprising: a dual constriction Y-shaped busbar comprising a first portion, and a first arm and a second arm extending parallel to each other from the first portion, the first arm comprising a first constriction and the second arm comprising a second constriction, a first sensor with a first threshold range positioned adjacent to and spaced away from the first constriction by a first distance and adapted to measure a first current range, and a second sensor with a second threshold range positioned adjacent to and spaced away from the second constriction by a second distance and adapted to measure a second current range, wherein a third current range of the wide range current sensor chip is broader than the first current range and the second current range, and wherein the dual constriction Y-shaped busbar is adapted to configure the first sensor and the second sensor in parallel in an electrical circuit. In a first example of the system, the second threshold range is approximately the same as the first threshold range. In a second example of the system, optionally including the first example, the wide range current sensor chip is adapted to electrically couple to one or more batteries and measure current to and from the one or more batteries. In a third example of the system, optionally including one or both of the first and second examples, the wide range current sensor chip is adapted to measure a high charging current, a low operating current, and currents therebetween flowing to and from one or more batteries in an electric or hybrid vehicle. In a fourth example of the system, optionally including one or more or each of the first through third examples, the first distance and the second distance are approximately equal, and wherein a first constriction width of the first constriction is greater than a second constriction width of the second constriction. In a fifth example of the system, optionally including one or more or each of the first through fourth examples, a first constriction width of the first constriction and a second constriction width of the second constriction are approximately equal, and wherein the first distance is greater than the second distance.

The disclosure also provides support for a wide range current sensor chip, comprising: a busbar comprising a straight busbar comprising a first portion, a second portion, and a first constriction between the first portion and the second portion, a first sensor with a first threshold range positioned adjacent to and spaced away from the first constriction by a first distance and adapted to measure a first current range, and a second sensor with a second threshold range approximately equal to the first threshold range adapted to measure a second current range, wherein a third current range of the wide range current sensor chip is wider than the first current range and the second current range. In a first example of the system, the busbar is adapted to configure the first sensor and the second sensor in series in an electrical circuit. In a second example of the system, optionally including the first example, the second sensor is positioned adjacent to and spaced away from the first constriction by a second distance greater than the first distance, opposite the first sensor across the first constriction. In a third example of the system, optionally including one or both of the first and second examples, the wide range current sensor chip further comprises a second constriction and a third portion, and wherein the second sensor is positioned adjacent to and spaced away from the second constriction by a second distance greater than the first distance. In a fourth example of the system, optionally including one or more or each of the first through third examples, the wide range current sensor chip further comprises a second constriction and a third portion, and wherein the second sensor is positioned adjacent to and spaced away from the second constriction by the first distance, and wherein a first constriction width of the first constriction is greater than a second constriction width of the second constriction. In a fifth example of the system, optionally including one or more or each of the first through fourth examples, the first current range is defined by a first upper threshold and a first lower threshold, the second current range is defined by a second upper threshold and a second lower threshold, and wherein the first upper threshold and the first lower threshold are greater than the second upper threshold and the second lower threshold, respectively.

FIGS. 1-13 show schematics of an example configuration with relative positioning of the various components. FIG. 13 is shown approximately to scale; though other relative dimensions may be used. As used herein, the term “approximately” is construed to mean plus or minus five percent unless otherwise specified. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. Moreover, the components may be described as they relate to reference axes included in the drawings.

Features described as axial may be approximately parallel with an axis referenced unless otherwise specified. Features described as counter-axial may be approximately perpendicular to the axis referenced unless otherwise specified. Features described as radial may circumferentially surround or extend outward from an axis, such as the axis referenced, or a component or feature described prior as being radial to a referenced axis, unless otherwise specified.

Features described as longitudinal may be approximately parallel with an axis that is longitudinal. A lateral axis may be normal to a longitudinal axis and a vertical axis. Features described as lateral may be approximately parallel with the lateral axis. A vertical axis may be normal to a lateral axis and a longitudinal axis. Features described as vertical may be approximately parallel with a vertical axis.

It will be appreciated that the configurations and routines disclosed herein are exemplary in nature, and that these specific embodiments are not to be considered in a limiting sense, because numerous variations are possible. Moreover, unless explicitly stated to the contrary, the terms “first,” “second,” “third,” and the like are not intended to denote any order, position, quantity, or importance, but rather are used merely as labels to distinguish one element from another. The subject matter of the present disclosure includes all novel and non-obvious combinations and sub-combinations of the various systems and configurations, and other features, functions, and/or properties disclosed herein.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A wide range current sensor chip, comprising:
a single busbar including one or more constrictions;
a first sensor with a first threshold range adapted to measure a first current range, positioned adjacent to one of the one or more constrictions and spaced away therefrom by a first distance; and
a second sensor with a second threshold range adapted to measure a second current range, positioned adjacent to one of the one or more constrictions and spaced away therefrom by a second distance, wherein a third current range of the wide range current sensor chip depends on the first threshold range, the second threshold range, the first distance, and the second distance.

2. The wide range current sensor chip of claim 1, wherein the wide range current sensor chip is adapted to be incorporated into an electrical circuit with the first sensor and the second sensor in parallel.

3. The wide range current sensor chip of claim 1, wherein the wide range current sensor chip is adapted to be incorporated into an electrical circuit with the first sensor and the second sensor in series.

4. The wide range current sensor chip of claim 1, wherein the busbar comprises only one constriction, and wherein the first sensor is positioned adjacent to and spaced away from a first side of a constriction, and the second sensor is positioned adjacent to and spaced away from a second side of the constriction, where the first side is opposite the second side.

5. The wide range current sensor chip of claim 4, wherein the first threshold range and the second threshold range are approximately the same, and wherein the first distance and the second distance are different.

6. The wide range current sensor chip of claim 4, wherein the first threshold range is not the same as the second threshold range, and wherein the first distance and the second distance are approximately the same.

7. The wide range current sensor chip of claim 1, wherein the busbar comprises two constrictions, and wherein the first sensor is positioned adjacent to and spaced away from a first constriction having a first constriction width by the first distance, and wherein the second sensor is positioned adjacent to and spaced away from a second constriction having a second constriction width by the second distance.

8. The wide range current sensor chip of claim 7, wherein the third current range further depends on the first constriction width, the second constriction width, and a difference therebetween.

9. A wide range current sensor chip, comprising:
a dual constriction Y-shaped busbar comprising a first portion, and a first arm and a second arm extending parallel to each other from the first portion, the first arm comprising a first constriction and the second arm comprising a second constriction;
a first sensor with a first threshold range positioned adjacent to and spaced away from the first constriction by a first distance and adapted to measure a first current range; and
a second sensor with a second threshold range positioned adjacent to and spaced away from the second constriction by a second distance and adapted to measure a second current range, wherein a third current range of the wide range current sensor chip is broader than the first current range and the second current range, and wherein the dual constriction Y-shaped busbar is adapted to configure the first sensor and the second sensor in parallel in an electrical circuit.

10. The wide range current sensor chip of claim 9, wherein the second threshold range is approximately the same as the first threshold range.

11. The wide range current sensor chip of claim 9, wherein the wide range current sensor chip is adapted to electrically couple to one or more batteries and measure current to and from the one or more batteries.

12. The wide range current sensor chip of claim 9, wherein the wide range current sensor chip is adapted to measure a high charging current, a low operating current, and currents therebetween flowing to and from one or more batteries in an electric or hybrid vehicle.

13. The wide range current sensor chip of claim 9, wherein the first distance and the second distance are approximately equal, and wherein a first constriction width of the first constriction is greater than a second constriction width of the second constriction.

14. The wide range current sensor chip of claim 9, wherein a first constriction width of the first constriction and a second constriction width of the second constriction are approximately equal, and wherein the first distance is greater than the second distance.

15. A wide range current sensor chip, comprising:
a busbar comprising a straight busbar comprising a first portion, a second portion, and a first constriction between the first portion and the second portion;
a first sensor with a first threshold range positioned adjacent to and spaced away from the first constriction by a first distance and adapted to measure a first current range; and
a second sensor with a second threshold range approximately equal to the first threshold range adapted to measure a second current range, wherein a third current range of the wide range current sensor chip is wider than the first current range and the second current range.

16. The wide range current sensor chip of claim 15, wherein the busbar is adapted to configure the first sensor and the second sensor in series in an electrical circuit.

17. The wide range current sensor chip of claim 15, wherein the second sensor is positioned adjacent to and spaced away from the first constriction by a second distance greater than the first distance, opposite the first sensor across the first constriction.

18. The wide range current sensor chip of claim 15, wherein the wide range current sensor chip further comprises a second constriction and a third portion, and wherein the second sensor is positioned adjacent to and spaced away from the second constriction by a second distance greater than the first distance.

19. The wide range current sensor chip of claim 15, wherein the wide range current sensor chip further comprises a second constriction and a third portion, and wherein the second sensor is positioned adjacent to and spaced away from the second constriction by the first distance, and wherein a first constriction width of the first constriction is greater than a second constriction width of the second constriction.

20. The wide range current sensor chip of claim 15, wherein the first current range is defined by a first upper threshold and a first lower threshold, the second current range is defined by a second upper threshold and a second lower threshold, and wherein the first upper threshold and the first lower threshold are greater than the second upper threshold and the second lower threshold, respectively.
